(19) United States
(12) Patent Application Publication
(10) Pub. No.: US 2009/0045455 A1
(43) Pub. Date: Feb. 19, 2009

(54) Nonvolatile memory device and method of fabricating the same

(75) Inventors: Kwang-soo Seol, Suwon-si (KR); Sang-jin Park, Pyeongtaek-si (KR); Sang-moo Choi, Yongin-si (KR); Hyo-sug Lee, Suwon-si (KR); Jung-hun Sung, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/219,465

(22) Filed: Jul. 23, 2008

(30) Foreign Application Priority Data
Aug. 13, 2007 (KR) 10-2007-0081459

(51) Int. Cl. H01L 29/792; H01L 21/28

(52) U.S. Cl. 257/324; 438/591; 257/E29.309; 257/E21.21

(57) ABSTRACT

Example embodiments relate to nonvolatile semiconductor memory devices using an electric charge storing layer as a storage node and fabrication methods thereof. An electric charge trap type nonvolatile memory device may include a tunneling film, an electric charge storing layer, a blocking insulation film, and a gate electrode. The blocking insulation film may be an aluminum oxide having an energy band gap larger than that of a γ-phase aluminum oxide film. An α-phase crystalline aluminum oxide film as a blocking insulation film may have an energy band gap of about 7.0 eV or more along with fewer defects. The crystalline aluminum oxide film may be formed by providing a source film (e.g., AlF₃ film) on or within a preliminary blocking insulation film (e.g., amorphous aluminum oxide film) and performing a heat treatment. Alternatively, an aluminum compound (e.g., AlF₃) may be introduced into the preliminary blocking insulation film by other diffusion methods or ion implantation. Accordingly, the ability of the memory device to maintain electric charges may be improved, the operating voltage for programming and erasing may be lowered, and the operating speed may be increased.

### PRIORITY STATEMENT

This application claims the benefit under 35 U.S.C. § 119 of Korean Patent Application No. 10-2007-0081459, filed on Aug. 13, 2007 in the Korean Intellectual Property Office (KIPO), the entire contents of which are incorporated herein by reference.

### BACKGROUND

1. Technical Field

Example embodiments relate to semiconductor memory devices and methods of fabricating semiconductor memory devices.

2. Description of the Related Art

Nonvolatile memory devices allow the storage and transfer of relatively large amounts of data. Nonvolatile memory devices are capable of maintaining a stored data in the absence of a continuous power supply.

Examples of higher capacity nonvolatile memory devices may include NAND flash memory devices. A NAND memory cell may include a floating gate and a control gate, wherein electric charges (e.g., data) may be stored in the floating gate, and the control gate may control the floating gate. However, a conventional NAND flash memory device having a conductive material (e.g., doped polysilicon) as a floating gate may experience increased parasitic capacitance between higher integrated adjacent memory cells.

To address the problem of parasitic capacitance, metal-oxide-insulator-oxide-semiconductor (MOIOS) memory devices have been suggested and researched. Examples of MOIOS memory devices may include silicon-oxide-nitride-oxide-semiconductor (SONOS) memory devices and metal-oxide-nitride-oxide-semiconductor (MONOS) memory devices. A SONOS memory device may use silicon as a control gate, while a MONOS memory device may use metal as a control gate.

To store electric charges, a MOIOS memory device may use an electric charge trap layer formed of silicon nitride (Si₃N₄) instead of a floating gate formed of polysilicon. Thus, the memory cell structure of an MOIOS memory device may include an oxide film, a nitride film, and an oxide film (ONO) sequentially deposited between a substrate and a control gate. When electric charges are trapped in the nitride film, the threshold voltage may be shifted.

### SUMMARY

Example embodiments may provide an electric charge trap type nonvolatile memory device having a lower operation voltage and an improved capacity for holding electric charges. Example embodiments may also provide a method of fabricating such a nonvolatile memory device.

An electric charge trap type nonvolatile memory device according to example embodiments may include a tunneling film, an electric charge storing layer, a blocking insulation film, and/or a gate electrode. The blocking insulation film may be an aluminum oxide having an energy band gap larger than that of a γ-phase aluminum oxide film.

The tunneling film may include silicon oxide. The electric charge storing layer may be a film layer, a nanodots layer, a mixed layer including a film interspersed with nanodots, or a multilayer structure having at least one of the film layer, the nanodots layer, and the mixed layer. The film may include a doped polysilicon, a silicon nitride, a metal oxide, or a combination thereof. The metal oxide may include at least one of HfO₂, La₂O₃, and ZrO₂. The nanodots may include at least one of silicon and a metal. The blocking insulation film may have an α-phase crystal structure. As a result, the blocking insulation film may have an energy band gap of about 7.0 eV or more. The gate electrode may include TaN and may have a work function of about 4.0 eV or more.

A method of fabricating an electric charge trap type nonvolatile memory device according to example embodiments may include forming a tunneling film, forming an electric charge storing layer, forming a blocking insulation film including an aluminum oxide having an α-phase crystal structure, and/or forming a gate electrode.

Forming the blocking insulation film may include forming a preliminary blocking insulation film on the electric charge storing layer, introducing an aluminum compound into the preliminary blocking insulation film, and crystallizing the preliminary blocking insulation film with the introduced aluminum compound.

Introducing the aluminum compound may include forming an AlF₃ film on the preliminary blocking insulation film and diffusing AlF₃ from the AlF₃ film into the preliminary blocking insulation film. Diffusing the AlF₃ into the preliminary blocking insulation film and crystallizing of the preliminary blocking insulation film may occur simultaneously. Introducing the aluminum compound may also include ion injecting AlF₃ into the preliminary blocking insulation film. Introducing the aluminum compound may further include other methods of diffusing the aluminum compound into the preliminary blocking insulation film from a source including the aluminum compound.

A source film including the aluminum compound may be formed such that the source film is sandwiched within the preliminary blocking insulation film. The aluminum compound in the source film may be diffused into the preliminary blocking insulation film by heat treating the preliminary blocking insulation film and the source film. The source film may include AlF₃. Crystallizing the preliminary blocking insulation film may include heat treating the preliminary blocking insulation film with the introduced aluminum compound at a temperature of about 800° C.-1200° C.

The memory device according to example embodiments may include a blocking insulation film (e.g., aluminum oxide film with an α-phase crystal structure) having an energy band gap of about 7.0 eV or more. Consequently, the memory device according to example embodiments may reduce or prevent the leakage of electric charges trapped in the electric charge storing layer through the blocking insulation film. Accordingly, the ability of the memory device to maintain electric charges may be improved, the operation voltage needed for programming and erasing may be lowered, and the operating speed may be increased.

### BRIEF DESCRIPTION OF THE DRAWINGS

The above and other features and advantages of the device and methods according to example embodiments may become more apparent upon review of the detailed description with reference to the attached drawings in which:

FIG. 1 is a cross-sectional view of an electric charge trap memory device according to example embodiments;

FIGS. 2-5 are cross-sectional views illustrating a method of fabricating the memory device of FIG. 1;

FIGS. 6 and 7 are cross-sectional views illustrating a method of transforming a γ-phase preliminary blocking insulation film into an α-phase blocking insulation film; and

FIG. 8 is a graph showing the result of an X-ray diffraction analysis of an aluminum oxide film crystallized using conventional methods.

### DETAILED DESCRIPTION OF EXAMPLE EMBODIMENTS

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A nonvolatile semiconductor memory according to example embodiments may be described with reference to the accompanying drawings. In the drawings, the thicknesses of layers or regions may have been exaggerated for purposes of clarity.

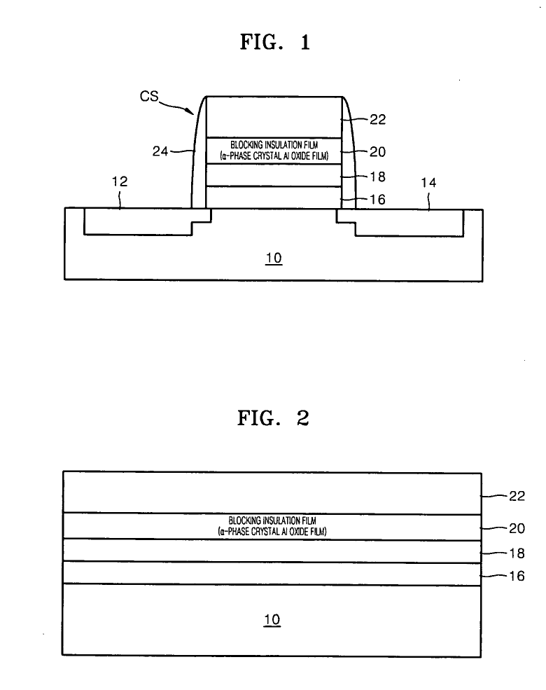

FIG. 1 is a cross-sectional view of an electric charge trap memory device according to example embodiments. Referring to FIG. 1, first and second impurity regions 12 and 14 may be provided on separate areas of a substrate 10. The substrate 10 may be a semiconductor substrate. For instance, the substrate 10 may be a silicon substrate (e.g., P-type silicon substrate). The first and second impurity regions 12 and 14 may include an impurity of a type opposite to that of the substrate 10. The first and second impurity regions 12 and 14 may be a lightly doped drain (LDD) structure. One of the first and second impurity regions 12 and 14 may be a source region, while the other one may be a drain region. A memory cell stack CS may be provided on the substrate 10 between the first and second impurity regions 12 and 14. The memory cell stack CS may also contact the first and second impurity regions 12 and 14.

The memory cell stack CS may include a tunneling film 16 on the substrate 10 between the first and second impurity regions 12 and 14. The tunneling film 16 may contact the first and second impurity regions 12 and 14. The memory cell stack CS may also include an electric charge storing layer 18, a blocking insulation film 20, and a gate electrode 22 sequentially deposited on the tunneling film 16. The memory cell stack CS may further include a gate spacer 24 covering the side surfaces of the tunneling film 16, the electric charge storing layer 18, the blocking insulation film 20, and the gate electrode 22. A NAND array may be formed by connecting a plurality of the memory devices of FIG. 1 to one another.

The tunneling film 16 may be an oxide film (e.g., a silicon oxide film) having a predetermined thickness in the memory cell stack CS. The electric charge storing layer 18 may be a nitride layer having a predetermined thickness and trap sites of a predetermined density (e.g., silicon nitride (Si₃N₄) film). The electric charge storing layer 18 may include any one of a silicon nitride (Si₃N₄) film, a metal nanodot, and a silicon nanodot. The electric charge storing layer 18 may also have a multilayered or mixed structure including at least two of the silicon nitride film, the metal nanodot, and the silicon nanodot. Furthermore, the electric charge storing layer 18 may be a doped polysilicon film, a silicon nitride film, a HfO₂ film, an La₂O₃ film, a ZrO₂ film, or a combination thereof. The blocking insulation film 20 may be an aluminum oxide film having an α-phase crystal structure. The gate electrode 22 may be a conductive layer having a work function of about 4.0 eV or more (e.g., tantalum nitride (TaN) layer). The gate spacer 24 may include silicon oxide (SiO₂).

In the operation of the memory device, electrons may be eliminated by neutralizing the electric charge storing layer 18. For instance, by applying about +17 V to the gate electrode 22, the memory device may be placed in a “0” state as a result of electrons being injected into the electric charge storing layer 18 from the substrate 10 through the tunneling film 16. On the other hand, by applying about +19 V to the substrate 10, the memory device may be placed in a “1” state as a result of holes being injected into the electric charge storing layer 18 from the substrate 10 through the tunneling film 16.

When electrons are being eliminated from the electric charge storing layer 18, back-tunneling electrons may be injected into the electric charge storing layer 18 from the gate electrode 22 through the blocking insulation film 20. The back-tunneling electrons may neutralize the holes being provided to the electric charge storing layer 18 from the substrate 10. As a result, the elimination of electrons may not occur smoothly. Accordingly, the elimination time may be prolonged and the elimination voltage may be increased. The elimination time may be shortened and the elimination voltage may be lowered by reducing or preventing back-tunneling. The reduction or prevention of back-tunneling may be achieved by blocking the electrons supplied to the electric charge storing layer 18 from the gate electrode 22 through the blocking insulation film 20.

The mechanism of leakage current (e.g., the flow of electrons from the gate electrode 22 to the blocking insulation film 20) may include Fowler-Nordheim (F-N) tunneling and Pool-Frenkel (P-F) conduction. According to F-N tunneling, the amount of leakage current may change according to the difference between the Fermi energy level of the gate electrode 22 and the energy of a conduction band of the blocking insulation film 20 (e.g., aluminium oxide film). For instance, the amount of leakage current may change according to the strength of the electric field applied to the blocking insulation film 20 and the energy barrier for the injection of electrons. As the energy barrier increases, the value of the F-N tunneling current in the same electric field may decrease.

According to P-F conduction, the value of the leakage current may be determined by a defect in the blocking insulation film 20 and the energy level of the defect. When the defect is relatively small, the value of the leakage current resulting from the P-F mechanism may decrease.

When the energy band gap of the blocking insulation film 20 is relatively small and a relatively large number of defects exist in the blocking insulation film 20, some of the electrons injected into the electric charge storing layer 18 from the substrate 10 during programming may flow into the blocking insulation film 20 and become trapped. The electrons trapped in the blocking insulation film 20 may be thermally unstable and, thus, may be easily leaked into the gate electrode 22. Because the electrons stored in the electric charge storing layer 18 may become thermally excited and flow into the conduction band of the blocking insulation film 20, the information maintenance characteristic (e.g., retention characteristic) of the memory device may deteriorate.

To improve programming and erasing as well as the retention of information, the blocking insulation film 20 may be formed of a substance having a relatively large energy band gap and relatively small defects. When the energy band gap of the blocking insulation film 20 is relatively large, it may be more difficult for the electric charges stored in the electric charge storing layer 18 to escape from the gate electrode 22 through the blocking insulation film 20. As the energy band gap of the blocking insulation film 20 increases, the leakage of electric charges through the blocking insulation film 20 from the electric charge storing layer 18 may be reduced.

The blocking insulation film 20 may be an aluminium oxide having an α-phase crystal structure. The α-phase aluminium oxide film may have a relatively stable spinel crystal structure with relatively few defects. The crystal structure may be formed at a temperature above about 1300° C. The α-phase aluminium oxide film may have an energy band gap above about 7.0 eV. For instance, the energy band gap may be about 8.6-9.0 eV or more.

The aluminum oxide in a conventional semiconductor device may have a metastable crystal structure (e.g., gamma, theta, or kappa structure) that may be formed between about 900° C.-1200° C. The aluminum oxide in a conventional semiconductor device may have an energy band gap of about 7.0 eV or less. For instance, an aluminum oxide having a gamma (γ) structure may include a plurality of oxygen vacancy defects.

Referring to FIG. 1, the memory device according to example embodiments may include a blocking insulation film 20 formed of an aluminum oxide having an α-phase crystal structure. As a result, the back-tunneling electrons injected from the gate electrode 22 into the blocking insulation film 20 during an erasing operation may be reduced or prevented. The leakage of electric charges stored in the electric charge storing layer 18 resulting from defects in the blocking insulation film 20 may also be reduced or prevented. Accordingly, a memory device having a lower erasing voltage and an improved electric charge retention may be achieved.

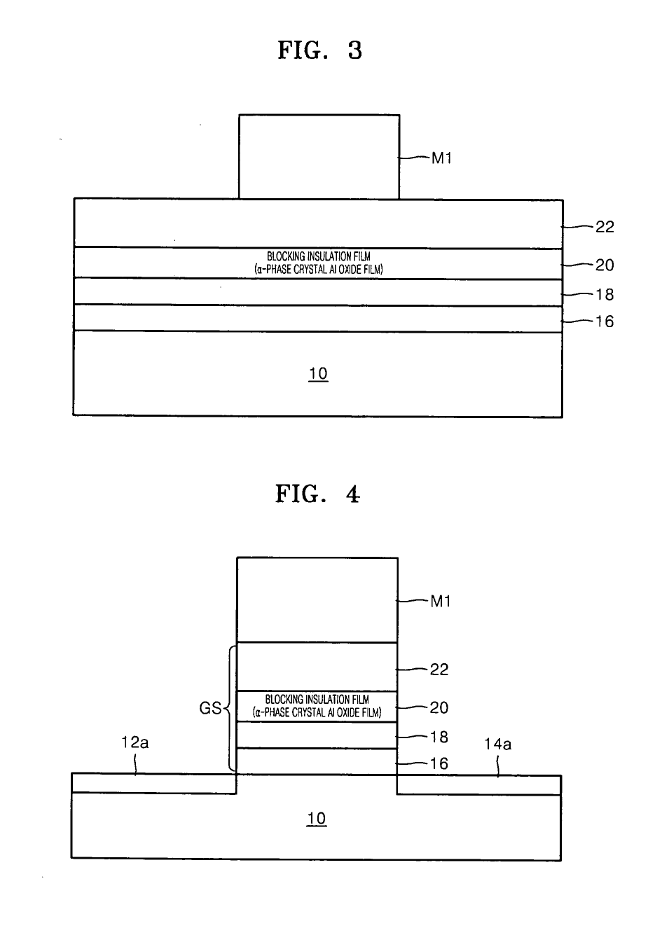

Referring to FIG. 2, a method of fabricating a memory device according to example embodiments may include forming a tunneling film 16 on the substrate 10 using a thermal oxidation method. The substrate 10 may be a silicon substrate. A electric charge storing layer 18 may be formed on the tunneling film 16 using a relatively low pressure chemical vapor deposition (LPCVD) method. The electric charge storing layer 18 may be formed of silicon nitride (Si₃N₄). A blocking insulation film 20 may be formed on the electric charge storing layer 18. The blocking insulation film 20 may be an aluminum oxide having an α-phase crystal structure. A gate electrode 22 may be formed on the blocking insulation film 20.

Referring to FIG. 3, a mask M1 may be formed on the gate electrode 22 so as to allow the sequential etching of the gate electrode 22, the blocking insulation film 20, the electric charge storing layer 18, and the tunneling film 16. The etched gate electrode 22, blocking insulation film 20, electric charge storing layer 18, and tunneling film 16 is shown in FIG. 4. Referring to FIG. 4, a gate stack GS may include the etched tunneling film 16, the electric charge storing layer 18, the blocking insulation film 20, and the gate electrode 22. Conductive impurities may be injected into the substrate 10 exposed by the etching to form first and second shallow impurity regions 12a and 14a in the substrate 10. The mask M1 may be removed before or after the formation of the first and second shallow impurity regions 12a and 14a.

Referring to FIG. 5, a gate spacer 24 may be formed on the side surface of the gate stack GS. First and second deep impurity regions 12b and 14b may be formed in the first and second shallow impurity regions 12a and 14a, respectively, by injecting conductive impurities into the substrate 10. The resulting first and second impurity regions 12 and 14 in the substrate 10 may be lightly doped drain (LDD) structures.

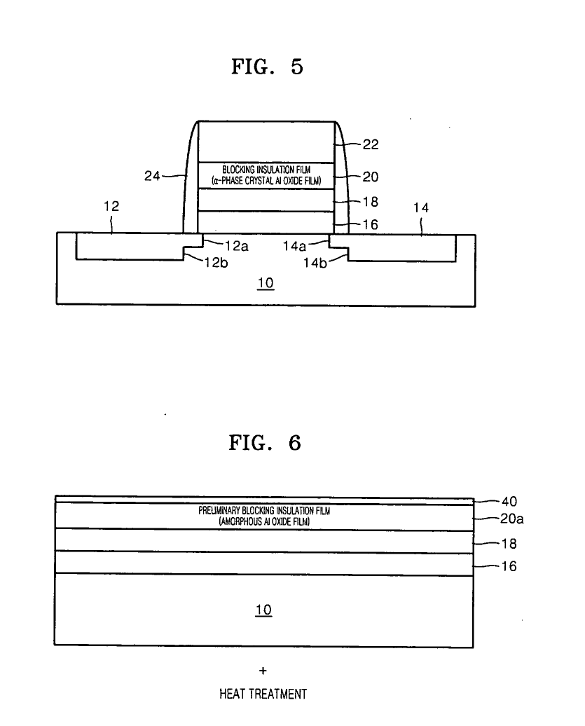

A method of forming the blocking insulation film 20 according to example embodiments so as to achieve an aluminum oxide film having an α-phase crystal structure will be described below in further detail. Referring to FIG. 6, a preliminary blocking insulation film 20a may be formed on the electric charge storing layer 18. For instance, the preliminary blocking insulation film 20a may be an amorphous aluminum oxide film. The preliminary blocking insulation film 20a may be deposited using an atomic layer deposition (ALD) method, a sputtering method, or a chemical vapor deposition (CVD) method. The preliminary blocking insulation film 20a may include a relatively large number of impurities and/or defects.

A source film 40 may be deposited on the preliminary blocking insulation film 20a. The source film 40 (e.g., AlF₃ film) may include an aluminum compound (e.g., AlF₃). The source film 40 may be formed to a thickness of about 1-5 nm. The source film 40 may facilitate the transformation of the preliminary blocking insulation film 20a into an α phase crystalline structure. The source film 40 may not only lower the α-phase nucleation energy but may also reduce the threshold energy of shifting from a γ-phase crystalline structure to an α-phase crystalline structure. The source film 40 may be heat treated at a temperature above about 800° C. and less than about 1200° C. As a result, the aluminum compound (e.g., AlF₃) of the source film 40 (e.g., AlF₃ film) may diffuse into the preliminary blocking insulation film 20a (e.g., amorphous aluminum oxide film).

Referring to FIG. 7, the preliminary blocking insulation film 20a (e.g., amorphous aluminum oxide film) may be transformed into a blocking insulation film 20 having an α-phase crystal structure (e.g., an aluminum oxide film having an α-phase crystal structure). Accordingly, a blocking insulation film 20 having an α-phase crystal structure may be formed on the electric charge storing layer 18.

It may be beneficial for the source film 40 (e.g., AlF₃ film) to be completely diffused into the preliminary blocking insulation film 20a (e.g. amorphous aluminum oxide film) during the heat treatment such that the source film 40 does not remain on the resulting blocking insulation film 20 after the heat treatment. Thus, the source film 40 may have a thickness such that the source film 40 will be completely diffused into the preliminary blocking insulation film 20a during the heat treatment depending on the time and/or temperature of the heat treatment. However, because the thickness of any source film 40 remaining after the heat treatment may be relatively thin, the remaining source film 40 may not affect subsequent processes or the characteristics of the memory device.

The diffusion of the source film 40 (e.g., AlF₃ film) and the crystallization of the preliminary blocking insulation film 20a (e.g., amorphous aluminum oxide film) may be separately performed. For example, a process may be performed to diffuse the source film 40 into the preliminary blocking insulation film 20a by heat treating the substrate 10 at a temperature lower than the crystallization temperature. A separate heat treatment may then be performed to crystallize the preliminary blocking insulation film 20a with the diffused aluminum compound (e.g., AlF₃).

As an alternative to forming the source film 40 on the preliminary blocking insulation film 20a, the source film 40 may be formed so as to be sandwiched within the preliminary blocking insulation film 20a. For instance, the source film 40 may be formed so as to divide the preliminary blocking insulation film 20a into an upper part and a lower part. As an alternative to introducing the aluminum compound into the preliminary blocking insulation film 20a by a heat treatment process, the aluminum compound may be introduced into the preliminary blocking insulation film 20a by other diffusion methods utilizing various types of sources. Furthermore, an aluminum compound may be introduced into the preliminary blocking insulation film 20a by ion implantation.

As described above, an aluminum compound (e.g., AlF₃) may be introduced into the preliminary blocking insulation film 20a (e.g., amorphous aluminum oxide film). The preliminary blocking insulation film 20a with the introduced aluminum compound may be heat treated to form the blocking insulation film 20. A gate electrode 22 may be formed on the blocking insulation film 20.

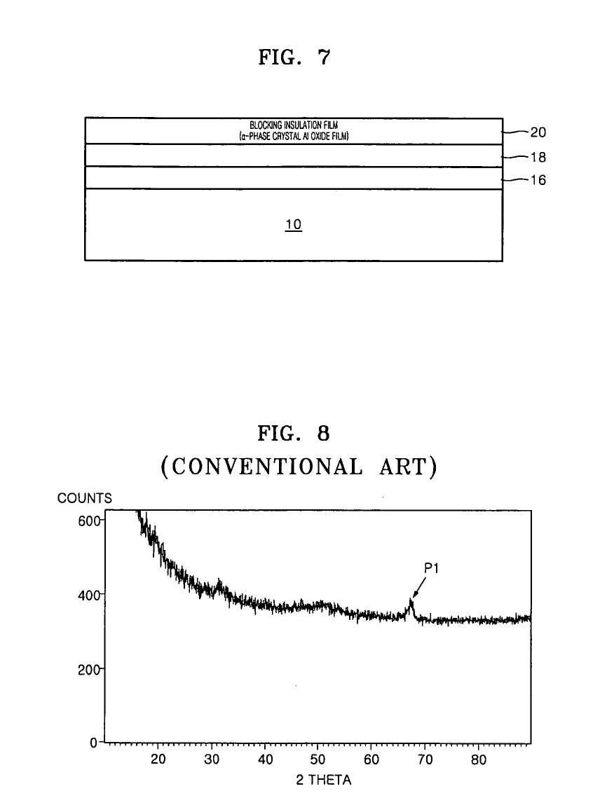

FIG. 8 is a graph showing the result of an X-ray diffraction analysis of a conventional aluminum oxide film formed by ALD and heat treated for one minute at a temperature of about 1100° C. without an AlF₃ film. Referring to FIG. 8, a peak P1 may be observed when the diffraction angle of the X-ray is between about 60°-70°, thus indicating that the crystallized aluminum oxide film has a γ-phase crystal structure. The peak P1 may be observed when the heat treatment is performed at a temperature between about 900° C.-1100° C. Although an aluminum oxide film with an α-phase crystal structure may occur with a heat treatment above about 1300° C., the substrate may thermally deform (e.g., bend) when the heat treatment temperature is above about 1200° C. Thus, performing a heat treatment at a temperature above about 1200° C. may be difficult.

The method of introducing an aluminum compound (e.g., AlF₃) into a preliminary blocking insulation film 20a (e.g., amorphous aluminum oxide film) according to example embodiments may be used to obtain an α-phase blocking insulation film 20 (e.g., α-phase aluminum oxide film) with a heat treatment of less than about 1200° C. Although an α-phase aluminum oxide film may be thermodynamically more stable, a γ-phase aluminum oxide film may facilitate easier nucleation, because the surface energy of the γ-phase aluminum oxide film may be lower than that of the α-phase aluminum oxide film. Thus, a crystallized aluminum oxide film formed by a heat treatment of about 1200° C. or less according to conventional methods may have a γ-phase crystal structure. While conventional methods may result in a γ-phase aluminum oxide film, the method according to example embodiments allows the formation of an α-phase aluminum oxide film at a temperature of about 1200° C. or less.

The dielectric constant of an aluminum oxide film is about 2.5 times higher than that of a silicon oxide film. In a cell structure having a continuous multilayered heterogeneous dielectric stack structure, the strength of an electric field formed at each dielectric layer by an electrode may be inversely proportional to the dielectric constant of that dielectric layer.

Thus, in the above-described cell structure according to example embodiments, when a voltage is applied to the gate electrode, the electric field applied to the tunneling film (e.g., silicon oxide film) may increase as the dielectric constant of the blocking insulation film increases. Accordingly, even when a relatively low voltage is applied to the gate electrode, the amount of electrons supplied to the electric charge storing layer from the substrate through the tunneling film may increase while the amount of electric charges leaking through the gate electrode may decrease.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A nonvolatile memory device comprising:
a tunneling film,
an electric charge storing layer,
a blocking insulation film, and
a gate electrode,
wherein the blocking insulation film is an aluminum oxide having an energy band gap larger than that of a γ-phase aluminum oxide film.

2. The nonvolatile memory device of claim 1, wherein the tunneling film includes silicon oxide.

3. The nonvolatile memory device of claim 1, wherein the electric charge storing layer is a film layer, a nanodots layer, a mixed layer including a film interspersed with nanodots, or a multilayer structure including at least one of the film layer, the nanodots layer, and the mixed layer.

4. The nonvolatile memory device of claim 3, wherein the film includes a doped polysilicon, a silicon nitride, a metal oxide, or a combination thereof.

5. The nonvolatile memory device of claim 4, wherein the metal oxide is at least one of HfO₂, La₂O₃, and ZrO₂.

6. The nonvolatile memory device of claim 3, wherein the nanodots include at least one of silicon and a metal.

7. The nonvolatile memory device of claim 1, wherein the blocking insulation film has an α-phase crystal structure.

8. The nonvolatile memory device of claim 1, wherein the blocking insulation film has an energy band gap of about 7.0 eV or more.

9. The nonvolatile memory device of claim 1, wherein the gate electrode has a work function of about 4.0 eV or more.

10. The nonvolatile memory device of claim 1, wherein the gate electrode includes TaN.

11. A method of fabricating a nonvolatile memory device comprising:
forming a tunneling film,
forming an electric charge storing layer,
forming a blocking insulation film including an aluminum oxide having an α-phase crystal structure, and
forming a gate electrode.

12. The method of claim 11, wherein forming the blocking insulation film includes
forming a preliminary blocking insulation film on the electric charge storing layer,
introducing an aluminum compound into the preliminary blocking insulation film, and
crystallizing the preliminary blocking insulation film with the introduced aluminum compound.

13. The method of claim 12, wherein introducing the aluminum compound includes
forming an AlF₃ film on the preliminary blocking insulation film; and
diffusing AlF₃ from the AlF₃ film into the preliminary blocking insulation film.

14. The method of claim 12, wherein introducing the aluminum compound includes
ion injecting AlF₃ into the preliminary blocking insulation film.

15. The method of claim 12, wherein introducing the aluminum compound includes
diffusing the aluminum compound into the preliminary blocking insulation film from a source including the aluminum compound.

16. The method of claim 13, wherein diffusing the AlF₃ into the preliminary blocking insulation film and crystallizing the preliminary blocking insulation film occur simultaneously.

17. The method of claim 12, further comprising:
forming a source film including the aluminum compound such that the source film is sandwiched within the preliminary blocking insulation film.

18. The method of claim 17, wherein the aluminum compound in the source film is diffused into the preliminary blocking insulation film by heat treating the preliminary blocking insulation film and the source film.

19. The method of claim 17, wherein the source film includes AlF₃.

20. The method of claim 12, wherein crystallizing the preliminary blocking insulation film includes
heat treating the preliminary blocking insulation film at a temperature of about 800° C.-1200° C.
